(19) United States
(12) Patent Application Publication
(10) Pub. No.: US 2014/0256068 A1
(43) Pub. Date: Sep. 11, 2014

(54) ADJUSTABLE LASER PATTERNING PROCESS TO FORM THROUGH-HOLES IN A PASSIVATION LAYER FOR SOLAR CELL FABRICATION

(71) Applicants: Jeffrey L. FRANKLIN, Albuquerque, NM (US); Yi ZHENG, Sunnyvale, CA (US); Michel Ranjit FREI, Palo Alto, CA (US); James M. GEE, Albuquerque, NM (US)

(72) Inventors: Jeffrey L. FRANKLIN, Albuquerque, NM (US); Yi ZHENG, Sunnyvale, CA (US); Michel Ranjit FREI, Palo Alto, CA (US); James M. GEE, Albuquerque, NM (US)

(21) Appl. No.: 13/790,941

(22) Filed: Mar. 8, 2013

(51) Int. Cl. H01L 21/66

(52) U.S. Cl. CPC H01L 22/12
USPC 438/16

(57) ABSTRACT

Embodiments of the invention contemplate formation of a high efficiency solar cell utilizing an adjustable or optimized laser patterning process to form openings with different geometry in a passivation layer disposed on a substrate based on different film properties in the passivation layer and the substrate. In one embodiment, a method of forming a solar cell includes transferring a substrate having a passivation layer formed on a back surface of a substrate into a laser patterning apparatus, performing a substrate inspection process by a detector disposed in the laser patterning apparatus, determining a laser patterning recipe configured to form openings in the passivation layer based on information obtained from the substrate inspection process, and performing a laser patterning process on the passivation layer using the determined laser patterning recipe.

### BACKGROUND OF THE INVENTION

1. Field of the Invention

Embodiments of the invention generally relate to the fabrication of back contact of photovoltaic cells, more particularly, a process of fabricating back contact through-holes in a passivation layer formed on a back surface of photovoltaic cells.

2. Description of the Related Art

Solar cells are photovoltaic devices that convert sunlight directly into electrical power. The most common solar cell material is silicon, which is in the form of single or multicrystalline substrates, sometimes referred to as wafers. Because the amortized cost of forming silicon-based solar cells to generate electricity is higher than the cost of generating electricity using traditional methods, there has been an effort to reduce the cost required to form solar cells.

Conventionally, solar cells using single crystal silicon substrate often have limitations, such as high cost or relatively smaller substrate size. Multicrystalline silicon (mc-Si) materials, such as nanocrystalline silicon or polycrystalline silicon, amorphous silicon, quasi-mono silicon material, cast-monocrystalline silicon material, or other related silicon materials, offer an alternative cost-effective option for silicon solar cells, compared with single crystalline silicon. Multicrystalline silicon (mc-Si), polycrystalline, nanocrystalline, amorphous or other related materials reduce the cell cost and increase the area of the active cells.

In most of these materials, a large number of grain boundaries and other defects are often present. Grain boundaries may create trap centers that can act as generation-recombination centers, potentially degrading short circuit current by recombining photogenerated carriers and fill factor and open circuit voltage by increasing the solar cell leakage current. Grain boundary effect in solar cells becomes important for multi-grained silicon substrates. Grain boundaries may also dramatically influence resistivity and conductivity in the solar cell substrate. Impurities in the substrates may adversely impact on solar cell conversion efficiency and reduce overall device performance.

Furthermore, a passivation layer is often deposited on a back surface of the solar cell substrate, providing a desired film property that reduces recombination of the electrons or holes in the solar cells and redirects electrons and charges back into the solar cells to generate photocurrent. When electrons and holes recombine, the incident solar energy is re-emitted as heat or light, thereby lowering the conversion efficiency of the solar cells. Openings are created in the passivation layer to form back metal contact to the substrate. However, geometry of the openings, such as sizes, densities, or dimensions formed thereof, often affect electrical performance of the solar cell devices. For example, excess opening areas formed in the passivation layer may decrease resistive losses as well as reduction of effectiveness of passivation. Furthermore, defects formed along with the grain boundaries as well as impurities found in the passivation layer may affect the passivating properties of the passivation layer formed on the solar cell. As discussed above, substrates with different resistivity may also need openings having a different geometry or different distance between the openings so as to optimize highest possible efficiency.

Therefore, there exists a need for improved methods and apparatus to form openings in a passivation layer formed on solar cell substrates fabricated from different materials and properties while maintaining good passivation film properties.

### SUMMARY OF THE INVENTION

Embodiments of the invention contemplate formation of a high efficiency solar cell device utilizing an adjustable or optimized laser patterning process to form openings with different geometries or distributions in a passivation layer. In one embodiment, a method of forming a solar cell includes transferring a substrate having a passivation layer formed on a back surface of a substrate into a laser patterning apparatus, performing a substrate inspection process by a detector disposed in the laser patterning apparatus, determining a laser patterning recipe configured to form openings in the passivation layer based on information obtained from the substrate inspection process, and performing a laser patterning process on the passivation layer using the determined laser patterning recipe.

In another embodiment, a method of forming an opening in a passivation layer on a back surface of a solar cell substrate includes receiving a substrate having a passivation layer formed on a back surface of a substrate into a laser patterning apparatus, the substrate fabricated from a crystalline silicon material having a first type of doping atom on the back surface of the substrate and a second type of doping atom on a front surface of the substrate, performing an inspection process on the passivation layer or the substrate in the laser patterning apparatus, adjusting a laser patterning recipe based on information detected from the optical inspection process in the laser patterning apparatus, and performing a laser patterning process using the adjusted laser patterning recipe in the laser patterning apparatus to form openings in the passivation layer.

In yet another embodiment, a method of forming an opening in a passivation layer on a back surface of a solar cell substrate includes receiving a substrate having a passivation layer formed on a back surface of a substrate into a laser patterning apparatus, the substrate fabricating from a crystalline silicon material having a first type of doping atom on the back surface of the substrate and a second type of doping atom on a front surface of the substrate, detecting film properties of the passivation layer or the substrate, determining a laser patterning recipe based on the film properties as detected, and performing a laser patterning process using the determined laser patterning recipe in the laser patterning apparatus.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings.

FIG. 1 depicts a schematic cross sectional view of a solar cell having a passivation layer formed on a back surface of a substrate;

FIG. 2 depicts a side view of one embodiment of a laser patterning apparatus that may be utilized to practice the present invention;

FIG. 3A depicts a top view of a solar cell substrate having grain boundaries formed therein;

FIG. 3B depicts a cross sectional view the solar cell of FIG. 1 with grain boundaries formed in the substrate; and

FIG. 4 a flow diagram of a method for performing a laser patterning process on a passivation layer of a solar cell according to embodiments of the invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the invention contemplate a laser patterning process to form through-holes in a passivation layer disposed on a substrate. Parameters of the laser patterning process may be varied to facilitate forming through-holes in a passivation layer having varying film properties formed from different materials or having different film types formed on the substrate. The laser patterning process may be adjusted in response to information obtained from inspection of materials of the passivation layer and the raw materials forming the substrate prior to performing the laser patterning process. The inspection process may assist in the selection of a laser patterning recipe used to form openings in the passivation layer so as to achieve improved solar cell device performance.

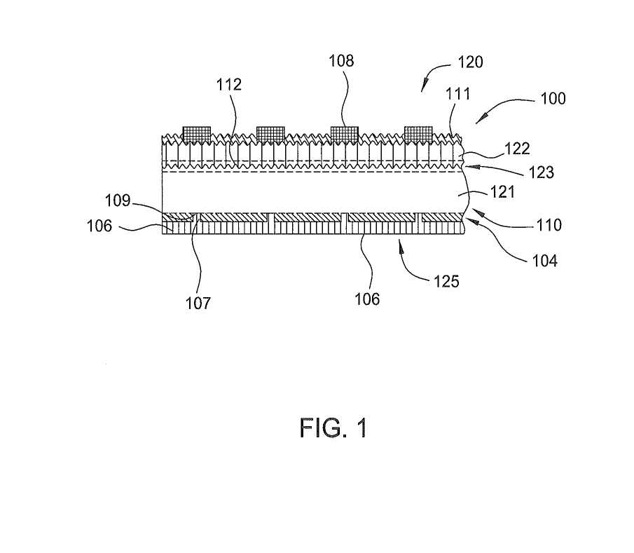

FIG. 1 depicts a cross sectional view of a silicon solar cell substrate 110 that may have a passivation layer 104 formed on a surface, e.g. a back surface 125, of the substrate 110. A silicon solar cell 100 is fabricated on a textured surface 112 on a front surface 120 of the solar cell substrate 110. The substrate 110 may be formed from any suitable type of semiconductor materials, including single crystalline silicon, monocrystalline silicon, multicrystalline silicon, polycrystalline silicon, nanocrystalline silicon, amorphous silicon or other suitable silicon containing materials. The substrate 110 includes a p-n junction region 123 disposed between a p-type base region 121 and an n-type emitter 122. The p-n junction region 123 is formed between the p-type base region 121 and the n-type emitter 122 to form a solar cell. An electrical current is generated when light strikes the front surface 120 of the substrate 110. The generated electrical current flows through metal front contacts 108 and metal backside contacts 106 formed on the back surface 125 of the substrate 110.

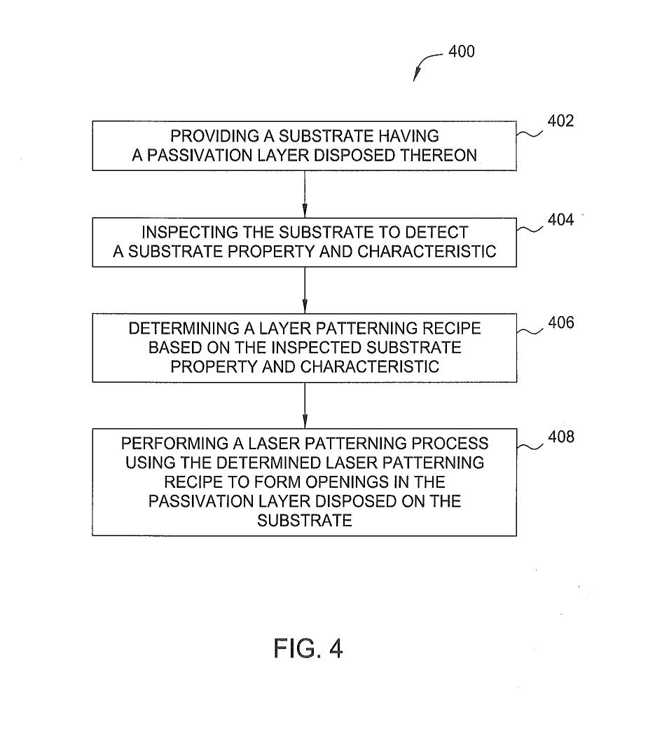

In one embodiment, the passivation layer 104 is disposed between the back contact 106 and the p-type base region 121 on the back surface 125 of the solar cell 100. The passivation layer 104 may be a dielectric layer providing good interface properties that reduce the recombination of the electrons and holes, drives and/or diffuses electrons and charge carriers back to the junction region 123, and minimizes light absorption. The passivation layer 104 is drilled and/or patterned to form openings 109 (e.g., back contact through-holes) that allow a portion, e.g., fingers 107, of the back contact 106 extending through the passivation layer 104 to be in electrical contact/communication with the p-type base region 121. The openings 109 may be formed by an adjustable laser patterning process described below with referenced to FIG. 4. The plurality of fingers 107 may be later formed in the openings 109 of the passivation layer 104 that are electrically connected to the back contact 106 to facilitate electrical flow between the back contact 106 and the p-type base region 121. The back contact 106 is formed in the passivation layer 104 by a metal paste process, which deposits metal into the openings 109 formed in the passivation layer 104. As the passivation layer 104 along with the p-type base region 121 of the substrate 110 may be formed by different materials and different resistivity/conductivity of the film layer may be different locally or globally across the substrate. Accordingly, process parameters of the laser patterning process may be adjusted based on different film properties for the passivation layer and/or the p-type base region 121 of the substrate 110 as detected.

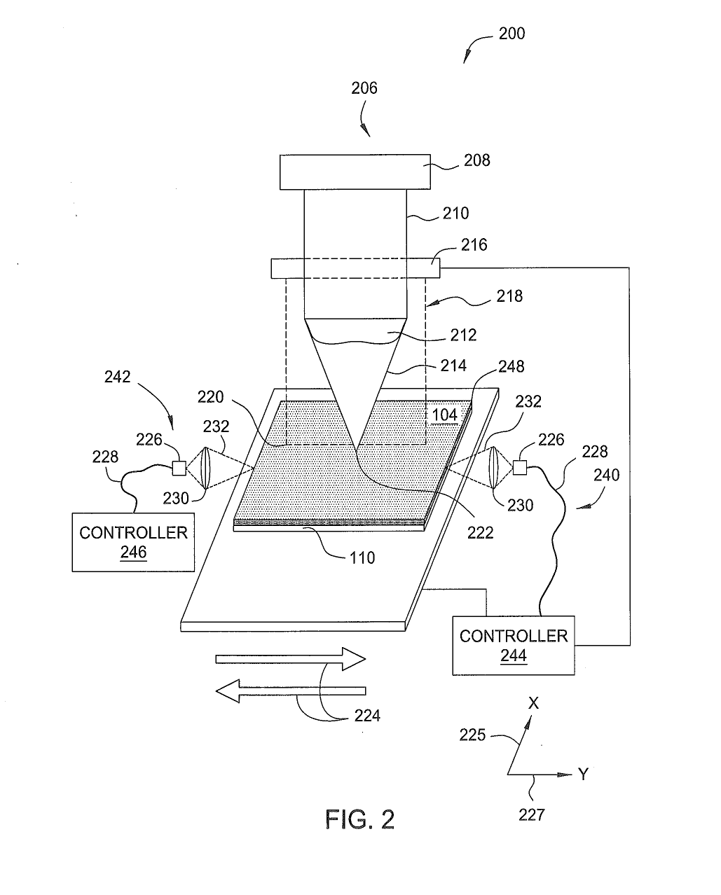

FIG. 2 depicts a laser patterning apparatus 200 that may be used to remove film material from a material layer to form openings in the material layer disposed on a substrate. In one embodiment, the laser patterning apparatus 200 comprises a laser module 206, a stage 202 configured to support a substrate, such as the substrate 110, during processing, and a translation mechanism 224 configured to control the movement of the stage 202. The laser module 206 comprises a laser radiation source 208 and a focusing optical module 210 disposed between the laser radiation source 208 and the stage 202.

In one embodiment, the laser radiation source 208 may be a light source made from Nd:YAG, Nd:YVO₄, crystalline disk, diode pumped fiber and other sources that can provide and emit a pulsed or continuous wave of radiation at a wavelength between about 180 nm and about 2000 nm, such as about 355 nm. In another embodiment, the laser radiation source 208 may include multiple laser diodes, each of which produces uniform and spatially coherent light at the same wavelength. In yet another embodiment, the power of the laser diode/s is in the range of about 10 Watts to 200 Watts.

The focusing optical module 210 transforms the radiation emitted by the laser radiation source 208 using at least one lens 212 into a line, or other suitable configurations, of radiation 214 directed at a material layer, such as the passivation layer 104 depicted in FIG. 1, disposed on the substrate 110. It is noted that the substrate 110 depicted in FIG. 2 is flipped over to be upside down to expose the passivation layer 104 disposed on the back surface 125 for a laser patterning process. The radiation 214 is scanned along on a surface of the passivation layer 104 disposed on the substrate to remove a portion of the passivation layer 104 to form openings therein. In one embodiment, the radiation 214 may scan the surface of the passivation layer 104 disposed on the substrate 110 as many times as needed until the openings are formed in the passivation layer 104 as desired.

Lens 212 of the focusing optical module 210 may be any suitable lens, or series of lenses, capable of focusing radiation into a line or spot. In one embodiment, lens 212 is a cylindrical lens. Alternatively, lens 212 may be one or more concave lenses, convex lenses, plane mirrors, concave mirrors, convex mirrors, refractive lenses, diffractive lenses, Fresnel lenses, gradient index lenses, or the like.

An detector 216 is disposed in the laser patterning apparatus 200 above the stage 202. In one embodiment, the detector 216 may be an optical detector may provide a light source with different wavelengths to inspect and detect film properties of the passivation layer 104 and/or the substrate 110 positioned on the stage 202. In one embodiment, the detector 216 and light source may form part of an optical microscope (OM) that may be used to view individual grains, grain boundaries, and interfaces formed in the passivation layer 104, the substrate 110 and therebetween. In another embodiment, the detector 216 may be a metrology tool or a sensor capable of detecting thickness, refractive index (n&k), surface roughness or resistivity on the passivation layer 104 and/or the substrate 110 prior to performing a laser patterning process. In yet another embodiment, the detector 216 may include a camera that may capture images of the passivation layer 104 and/or the substrate 110 so as to analyze the passivation layer 104 and/or the substrate 110 based on the image color contrast, image brightness contrast, image comparison and the like. In another embodiment, the detector 216 may be any suitable detector that may detect different film properties or characteristics of the substrate or the film layers disposed on the substrate.

The detector 216 may linearly scan the substrate surface using a line of optical radiation 218 provided therefrom across a linear region 220 of the substrate 110. The detector 216 may scan the substrate 110 as the substrate 110 advances in an X-direction 225. Similarly, the detector 216 may scan the substrate 110 as the substrate 110 moves in a Y-direction 227 as the translation mechanism 224 moves the stage 202.

The light source of the detector 216 may include one more infrared light sources providing a wavelength between about 600 nm and about 1500 nm. In the exemplary embodiment depicted in FIG. 2, an array of light sources may be disposed in the detector 216 so as to emit a line of optical radiation 218 to the substrate 110. Alternatively, the numbers of the light sources provided from the detector 216 may be varied in any configuration or any arrangement as needed. The detector 216 may be coupled to a controller 244, so as to control movement and data transfer from the detector 216 to the laser patterning apparatus 200. The controller 244 may be a high speed computer configured to control the detector 216 and/or the laser module 206 to perform an optical detection process or a laser patterning process. In one embodiment, the optical detection process is performed by the detector 216 prior to the laser patterning process, so that the process parameters set in a laser patterning recipe for performing a laser patterning process may be based on the measurement data received from the optical detection process.

Optionally, a first and a second optical devices 240, 242 may be disposed on the sides of the substrate 110 so as to view the substrate 110 and the passivation layer 104 from opposite edge surfaces 248. The optical device 240, 242 may have a signal generator 226 configured to provide an optical radiation to pass through a focusing len 230, forming a focusing beam 232, aiming at circumferential edge surfaces 248, e.g., both edges or four edge sides, of the substrate 110. The position of the first and the second optical devices 240, 242, is selected at a position close to, but not in contact with, the substrate 110 so that as the substrate 110 advances during measurement, the light signal from the optical devices 240, 242 may always impinge the circumferential edge(s) 248. The first and the second optical devices 240, 242 may both be coupled to the controller 244 through a wire 228 so that the controller 244 may control scan speed or optical detection to the substrate. Alternatively, the second optical device 242 may be coupled to a separate controller 246 as needed to separately and individually control the measurement process.

The laser patterning apparatus 200 may include the translation mechanism 224 configured to translate the stage 202 and the radiation 214 relative to one another. The translation mechanism 224 may be configured to move the stage 202 in different directions. In one embodiment, the translation mechanism 224 coupled to the stage 202 is adapted to move the stage 202 relative to the laser module 206 and/or the detector 216. In another embodiment, the translation mechanism 224 is coupled to the laser radiation source 208 and/or the focusing optical module 210 and/or the detector 216 to move the laser radiation source 208, the focusing optical module 210, and/or the detector 216 to cause the beam of energy to move relative to the substrate 110 that is disposed on the stationary stage 202. In yet another embodiment, the translation mechanism 224 moves the laser radiation source 208 and/or the focusing optical module 210, the detector 216, and the stage 202. Any suitable translation mechanism may be used, such as a conveyor system, rack and pinion system, or an x/y actuator, a robot, or other suitable mechanical or electro-mechanical mechanism to use for the translation mechanism 224. Alternatively, the stage 202 may be configured to be stationary, while a plurality of galvanometric heads (not shown) may be disposed around the substrate edge to direct radiation from the laser radiation source 208 to the substrate edge as needed.

The translation mechanism 224 may be coupled to the controller 244 to control the scan speed at which the stage 202, the line of radiation 214, and line of optical radiation 118 move relative to one another. The controller 244 may receive data from the detector 216 as well as the optical devices 240, 242 to generate an optimized laser patterning recipe that is used to control the laser module 206 to perform an optimized laser patterning process. The stage 202 and the radiation 214 and/or the optical radiation 118 are moved relative to one another so that the delivered energy translates to desired regions 222 of the passivation layer 104 formed on the substrate 110. In one embodiment, the translation mechanism 224 moves at a constant speed. In another embodiment, the translation of the stage 202 and movement of the line of radiation 214 and/or the line of optical radiation 118 follow different paths that are controlled by the controller 244.

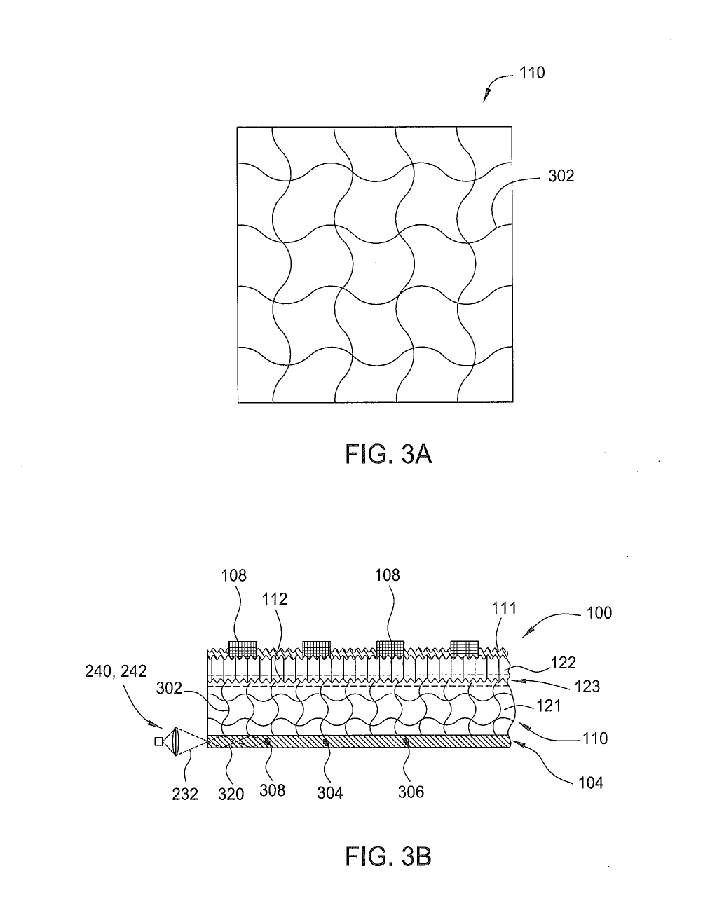

FIG. 3A depicts a top view of an image of the substrate 110 captured by the detector 216 during a substrate inspection process. As discussed above, the substrate 110 as utilized may be a multicrystalline silicon material, grain boundaries 302 may be found in the substrate 110. FIG. 3B depicts a cross sectional view of the substrate 110 having the solar cell 100 formed thereon. In one example, as shown in FIG. 3B which is a cross-sectional view of the substrate 110, grain boundaries 302 are found in the p-type region 121 of the substrate 110. Some film defects, such as interfacial defects, cracks, particles, micropits 304, 306, 308, grain boundaries 302 or dislocations formed in the passivation layer 104 may also be observed and detected by the detector 216 or the optical devices 240, 242. In one embodiment, the defects can be detected as variation in image contrast and density, such as gray scale of image. It is believed that image contrast (e.g., gray scale of image) or density is proportional to the lifetime of the silicon material locally in the solar cell substrate.

As discussed above, the passivation layer 104 and the substrate 110 may sometimes have grain boundaries 302 and film defects, such as interfacial or crystalline defects, particles, cracks, micropits 308, 306, 304, grain boundaries 302 or dislocations found therein. Film defects and grain boundaries found in the passivation layer 104 and the substrate 110 may dramatically affect the resistivity and the electrical performance of the solar cell 100. Interconnections formed close, adjacent, or on the film impurities or grain boundaries in the passivation layer 104 or the substrate 110 may adversely increase likelihood of a short circuit type of detect or device failure. Accordingly, an adjustable laser patterning process is provided herein to provide an adjustable laser patterning recipe that may be selected or adjusted based on the measurement information as detected on the passivation layer 104 and the substrate 110 prior to performing the laser patterning process using one or more of the detector 216 or the optical devices 240, 242. The laser patterning recipe may be adjusted to locally form openings 109 in the passivation layer 104, as shown in FIG. 1, with specific geometry, distribution or pattern in response to the different local resistivity, electrical properties or film properties (e.g., film characteristics) may be detected due to grain boundaries or other film defects as formed to improve the performance of the solar cell 100. Furthermore, the adjustable laser patterning recipe may drill openings 109 at certain positions locally in the passivation layer 104 as well as repairing defects, such as removing cracks, particles, grain boundaries or dislocations, from the passivation layer 104. Furthermore, the adjustable laser patterning recipe may be configured to drill openings 109 in the passivation layer 104 at a specific density or sizes so as to accommodate the substrate 110 fabricated from different crystalline materials while maintaining electrical performance of the solar cell 100 at a desired level. Details of the adjustable laser patterning process is described below with referenced to FIG. 4.

FIG. 4 depicts a flow diagram of a process 400 for laser patterning on the passivation layer 104 disposed on the back surface 125 of the substrate 110 for forming a solar cell device. The laser patterning process may be performed by a laser patterning apparatus, such as the laser patterning apparatus 200 described above with referenced to FIG. 2, or other suitable device. Prior to performing the laser patterning process, an optical inspection process may be performed to provide substrate/passivation layer film properties or characteristic information to the laser patterning apparatus 200, so as to beneficially select or adjust the laser patterning recipe used to perform the laser patterning process. It is contemplated that the process 400 may be adapted to be performed in any other suitable processing apparatus, including those available from other manufacturers, to form openings in a passivation layer disposed on a substrate. It should be noted that the number and sequence of steps illustrated in FIG. 4 are not intended to limiting as to the scope of the invention described herein, since one or more steps can be added, deleted and/or reordered as appropriate without deviating from the basic scope of the invention described herein.

The process 400 begins at step 402 by transferring a substrate, such as the substrate 110 having the passivation layer 104 disposed on the back side 125 of the substrate 110, into a laser patterning apparatus, such as the laser patterning apparatus 200 depicted in FIG. 2, to form openings in the passivation layer 104, as depicted in FIG. 1. As discussed above with referenced to FIG. 1, the substrate 110 may be a multicrystalline, polycrystalline, nanocrystalline, or amorphous silicon type solar cell substrate having the textured surface 112. In one example, the substrate 110 includes the p-type base region 121, the n-type emitter 122, and the p-n junction region 123 disposed therebetween. The n-type emitter 122 may be formed by doping a deposited semiconductor layer with certain types of elements (e.g., phosphorus (P), arsenic (As), or antimony (Sb)) in order to increase the number of negative charge carriers, i.e., electrons. In one embodiment, the n-type emitter 122 is formed by use of an amorphous, microcrystalline, nanocrystalline, or polycrystalline CVD deposition process that contains a dopant gas, such as a phosphorus containing gas (e.g., PH₃). The passivation layer 104 is disposed on the p-type base region 121 on the back surface 125 of the solar cell 100. The passivation layer 104 may be a dielectric layer providing good interface properties that reduce the recombination of the electrons and holes, drives and/or diffuses electrons and charge carriers back to the junction region 123. In one embodiment, the passivation layer 104 may be fabricated from a dielectric material selected from a group consisting of silicon nitride (Si₃N₄), silicon nitride hydride (SiₓN_{y}:H), silicon oxide, silicon oxynitride, a composite film of silicon oxide and silicon nitride, a composite film of silicon nitride and aluminum oxide layer, an aluminum oxide layer, a tantalum oxide layer, a titanium oxide layer, or other suitable material. In an exemplary embodiment, the passivation layer 104 is a composite layer having a first dielectric layer disposed on a second dielectric layer on the substrate 110. In one embodiment, the first dielectric layer is a silicon nitride layer and the second dielectric layer is an aluminum oxide layer (Al₂O₃) disposed on the back surface 125 of the substrate 110. The silicon nitride layer and the aluminum oxide layer (Al₂O₃) may be formed by any suitable deposition techniques, such as atomic layer deposition (ALD) process, plasma enhanced chemical vapor deposition (PECVD) process, metal-organic chemical vapor deposition (MOCVD), sputter process or the like. The aluminum oxide layer (Al₂O₃) is formed by an ALD process having a thickness between about 5 nm and about 100 nm and the silicon nitride layer may be formed by a CVD process having a thickness between about 50 nm and about 400 nm. The passivation layer 104 is formed on the back surface 125 of the substrate 110 ready to form openings 109 therein by the process 400 that later allows fingers of the back metal contact 106 to be filled. The detail of the process 400 with regard to forming openings 109 in the passivation layer 104 will be described further below.

At step 404, a substrate inspection process may be performed to inspect the passivation layer 104 and the substrate 110. As discussed above, defects and grain boundaries found in the passivation layer 104 and the substrate 110 may significantly affect device performance locally or globally across the substrate 110. As such, by performing a substrate inspection process prior to the laser patterning process, a specific or particular arranged laser patterning recipe may be selected to form openings 109 in the passivation layer 104 in accordance with the particular film properties, characteristics, or grain structures present on one or both of passivation layer 104 and the substrate 110.

In one embodiment, the substrate inspection process may be performed by emitting a light radiation from the light detector, such as the light detector 216 disposed in the laser patterning apparatus 200. The light signal transmitted to the substrate 110, or the passivation layer 104 disposed on the substrate 110, may be reflected from the substrate and being collected by the light detector 216 for analysis. The light radiation as emitted to the substrate detect and measure the locations and sizes of the impurities, film thickness, film resistivity, film characteristics, lifetime of the passivation layer 104 and/or the substrate 110. In addition, by viewing the substrate 110 through the light detector 216, grain boundaries, as well as film cracks, particles, micropits, grain boundaries, dislocations, or other optical visible defects may be obtained and used to determine an improved laser patterning recipe for drilling openings 109 in the passivation layer 104 that produces a better device performance of solar cell 100. For example, when the passivation layer 104 is detected to have a relatively higher resistivity, such as greater than 5 ohm-cm, a greater number of the openings 109 or shorter distance between the openings 109 may be utilized so as to compensate for the high resistivity found in the passivation layer 104 and/or the substrate 110. In the cases wherein a crack, particle or defect is found in the passivation layer 104, the location of the openings 109 may be selected to coincide with at the same location as the crack, particle or defect is found in the passivation layer 104 so as to remove such defect from the substrate 110, e.g., repairing the film, as well as maintaining the film electrical properties as desired.

In one embodiment, the substrate inspection process as performed at step 404 may detect locations and sizes of the impurities, film thickness, film resistivity, lifetime in the passivation layer 104 and detect locations of the grain boundaries, grain sizes, resistivity, carrier lifetime on the substrate 110.

At step 406, a laser patterning recipe determination process is performed to determine (i.e., select or adjust) a optimized laser patterning recipe for drilling/patterning openings 109 in the passivation layer 104. Based on the data received and obtained from the substrate inspection process performed at step 404, optimized process parameters may be determined to set up a laser patterning recipe to drill/pattern openings 109 in the passivation layer 104 with specific pattern design, layout, density, geometry or the like, either globally or locally across the substrate. In the embodiment wherein the substrate resistivity is detected to be greater than 5 ohm-cm, a pattern density of the openings 109 may be configured to be greater than 5 percent of the area or the distance among the openings 109 formed in the passivation layer 104 may be controlled about less than 500 nm.

Furthermore, during laser patterning recipe determination process, detection for locations of the grain boundaries formed in the substrate 110 may also be utilized to adjust the laser patterning recipe. For example, the openings 109 formed in the passivation layer 104 may be selected to be formed at locations away from the grain boundaries formed in the substrate 110, so as to avoid creating current leakage or short circuits created by forming metal contacts on the grain boundaries. Shunt defects may also be detected by the detector 216, such as by a light beam induced current image, to determine an opening pattern that may be used for the subsequent laser patterning process. Locations and/or pattern of the openings to be formed in the passivation layer 104 may also be selected to be formed at locations where impurities or defects, such as cracks or particles, are found, so as to remove cracks or particles from the passivation layer 104 to ablate away the defects. In some cases, the openings pattern determined to be formed in the passivation layer 104 may also be determined in accordance with substrate lifetime pattern as detected by photoluminescence (PL) process provided from the detector 216.

At step 408, a laser patterning process is performed on the passivation layer 104 using the laser patterning recipe determined at step 406. In one embodiment, the laser patterning process is performed by applying a series of laser pulses onto the passivation layer 104 to form the openings 109 in the passivation layer 104 based on the laser patterning recipe determined using the measurement data obtained at step 404. The bursts of laser pulses may have a laser of wavelength greater than 300 nm, for example between about 300 nm and about 800 nm, such as greater than 530 nm, for example about 532 nm, so called green laser. Each pulse is focused or imaged to a spot at certain regions of the passivation layer 104 to form openings 109 therein. Each pulse is focused and is directed so that the first spot is at the start position of an opening to be formed in the passivation layer 104 based on the optimized recipe as determined at step 406. Each opening 109 as formed in the passivation layer 104 may or may not have equal distance from each other. Alternatively, each opening 109 may be configured to have different distances from one another, or may be spaced/located in any manner as needed based on the film properties, materials, or defects as detected in the passivation layer 104 and the substrate 110.

In one embodiment, the spot size of the laser pulse is controlled at between about 80 μm and about 150 μm, such as about 100 μm. The spot size of the laser pulse may be configured in a manner to form openings 109 in the passivation layer 104 with desired dimension and geometries. In one embodiment, a spot size of a laser pulse about 200 μm may form an opening 109 in the passivation layer 104 with a diameter about between 80 μm and about 120 μm based on different laser intensity provided.

The laser pulse may have energy density (e.g., fluence) between about 200 microJoules per square centimeter (mJ/cm²) and about 1000 microJoules per square centimeter (mJ/cm²), such as about 500 microJoules per square centimeter (mJ/cm²) at a frequency between about 30 kHz and about 2 MHz. Each laser pulse length is configured to have a duration of about 10 picoseconds up to 10 nanoseconds. A single laser pulse may be used to form the openings 109 in the passivation layer 104 exposing the underlying substrate 110. After a first opening is formed in a first position defined in the passivation layer 104, a second opening is then consecutively formed by positioning the laser pulse (or substrate) to direct the pulse to a second location where the second opening desired to be formed in the passivation layer 104, according to the parameters in the recipe determined at step 406. The laser patterning process is continued until a desired number/pattern/geometry of the openings 109 are formed in the passivation layer 104.

After the laser patterning process, the substrate 110 can then be removed from the laser patterning apparatus. Subsequently, a plurality of fingers 107 and a back metal contact 106 can be formed and fill in the openings 109 formed in the passivation layer 104, as previously discussed in FIG. 1. The plurality of fingers 107 and the back metal contact 106 facilitates electrical flow between the back contact 106 and the p-type base region 121. In one embodiment, the back contact 106 disposed on the back surface 125 of the substrate 110 using a screen printing process performed in a screen printing tool, which is available from Baccini S.p.A, a subsidiary of Applied Materials, Inc. In one embodiment, the back contact 106 is heated in an oven to cause the deposited material to densify and form a desired electrical contact with the substrate back 125. It is noted other processes, such as a cleaning process, a rinse process, or other suitable process may be performed after the densifying process at step 406, before the metal back deposition process

Thus, the present application provides methods for forming openings in a passivation layer on a back side of a solar cell with beneficial opening pattern, density and geometry. The methods advantageously form openings in a passivation layer by an adjustable laser patterning process which may include optimized laser patterning recipe based on the measurement information obtained and detected from the passivation layer and the substrate. By performing an optical measurement process prior to the laser patterning process, a laser patterning process may be selected based on the specific film properties detected from a specific passivation layer and the solar cell substrate is obtained. The laser patterning process efficiently reduces the likelihood of short circuit, reduces recombination rate and advantageously improves the overall solar cell conversion efficiency and electrical performance.

While the foregoing is directed to embodiments of the present invention, other and further embodiments of the invention may be devised without departing from the basic scope thereof, and the scope thereof is determined by the claims that follow.

What is claimed is:

1. A method of forming a solar cell, comprising:
transferring a substrate having a passivation layer formed on a back surface of a substrate into a laser patterning apparatus;
performing a substrate inspection process by a detector disposed in the laser patterning apparatus;
determining a laser patterning recipe configured to form openings in the passivation layer based on information obtained from the substrate inspection process; and
performing a laser patterning process on the passivation layer using the determined laser patterning recipe.

2. The method of claim 1, wherein the passivation layer includes a film stack having a first dielectric layer formed on a second dielectric layer which is formed on the back surface of the substrate.

3. The method of claim 2, wherein the first dielectric layer is a silicon nitride layer and the second dielectric layer is an aluminum oxide layer.

4. The method of claim 1, wherein performing the laser patterning process further comprises:
providing a plurality of laser energy pulses at a wavelength greater than about 600 nm.

5. The method of claim 1, wherein performing the substrate inspection process further comprises:
receiving a light radiation from the detector, wherein the light radiation is received from a surface of the passivation layer; and
detecting defects formed in the passivation layer using the light radiation.

6. The method of claim 5, wherein the defects are at least one of interfacial defects, particles, cracks, micropits, grain boundaries or dislocations.

7. The method of claim 5, wherein the light signal has a wavelength between about 600 nm and about 1500 nm.

8. The method of claim 5, wherein the openings remove defects from the passivation layer.

9. The method of claim 1, wherein performing the substrate inspection process further comprises:
receiving a light radiation from the detector, wherein the light radiation is received from a surface of the passivation layer; and
detecting locations of grain boundaries formed in the substrate.

10. The method of claim 1, wherein performing the substrate inspection process further comprises:
receiving a light radiation from the detector, wherein the light radiation is received from a surface of the passivation layer; and
detecting resistivity of the substrate.

11. The method of claim 10, wherein the laser patterning recipe is determined in response to the measured resistivity detected from the substrate.

12. The method of claim 10, wherein a pattern density of the openings formed in the passivation layer is configured to be greater than 5 percent when a substrate resistivity greater than 5 ohm-cm is detected.

13. The method of claim 1, wherein performing the substrate inspection process further comprises:
inspecting the substrate from an edge of the substrate.

14. The method of claim 1, wherein the substrate is formed from a material selected from a group consisting of muiticrystalline silicon, amorphous silicon, nanocrystalline, or polycrystalline silicon.

15. The method of claim 1, wherein determining the laser patterning recipe further comprises:
determining geometry of the openings formed in the passivation layer.

16. A method of forming an opening in a passivation layer on a back surface of a solar cell substrate, comprising:
receiving a substrate having a passivation layer formed on a back surface of a substrate into a laser patterning apparatus, the substrate fabricated from a crystalline silicon material having a first type of doping atom on the back surface of the substrate and a second type of doping atom on a front surface of the substrate;
performing an inspection process on the passivation layer or the substrate in the laser patterning apparatus;
adjusting a laser patterning recipe based on information detected from the optical inspection process in the laser patterning apparatus; and
performing a laser patterning process using the adjusted laser patterning recipe in the laser patterning apparatus to form openings in the passivation layer.

17. The method of claim 16, wherein performing the optical inspection process further comprising:
providing a light signal to the substrate, wherein the light signal has a light wavelength between about 600 nm and about 1500 nm.

18. The method of claim 16, wherein performing the laser patterning process further comprises:
transmitting a laser energy to the substrate having a wavelength between about 300 nm and about 800 nm.

19. The method of claim 16, wherein performing the inspection process further comprising:
detecting defects or resistivity in at least one of the passivation layer or in the substrate.

20. The method of claim 16, wherein performing the inspection process further comprising:
detecting grain boundaries in the substrate.

21. A method of forming an opening in a passivation layer on a back surface of a solar cell substrate, comprising:
receiving a substrate having a passivation layer formed on a back surface of a substrate into a laser patterning apparatus, the substrate fabricating from a crystalline silicon material having a first type of doping atom on the back surface of the substrate and a second type of doping atom on a front surface of the substrate;
detecting film properties of the passivation layer or the substrate;
determining a laser patterning recipe based on the film properties as detected; and
performing a laser patterning process using the determined laser patterning recipe in the laser patterning apparatus.

22. The method of claim 21, wherein the detected film properties include impurities formed in the passivation layer.

23. The method of claim 21, wherein the detected film properties include grain boundaries formed in the substrate.

24. The method of claim 21, wherein the detected film properties include resistivity of the passivation layer or the substrate.
